(19) United States
(12) Patent Application Publication
(10) Pub. No.: US 2007/0222079 A1
(43) Pub. Date: Sep. 27, 2007

(54) Method of manufacturing wiring substrate, and liquid ejection head manufactured by same

(75) Inventor: Hiroshi Ohta, Kanagawa-ken (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/727,567

(22) Filed: Mar. 27, 2007

(30) Foreign Application Priority Data
Mar. 27, 2006 (JP) 2006-086463

(51) Int. Cl. H01L 23/52; H01L 23/48; H01L 29/40

(52) U.S. Cl. 257/758

(57) ABSTRACT

The method of manufacturing a wiring substrate includes the steps of: forming a photocatalyst containing layer which is made of a material containing a photocatalytic material, on a substrate made of an insulating material; forming a resin layer in regions other than wire regions on the photocatalyst containing layer; radiating ultraviolet light on the photocatalyst containing layer while the substrate provided with the resin layer and the photocatalyst containing layer is immersed in a solution containing at least a metal ion and a sacrificial reagent, in such a manner that metal is deposited on exposed regions of the photocatalyst containing layer.

### BACKGROUND OF THE INVENTION

1. Field of the Invention

The present invention relates to a method of manufacturing a wiring substrate and to a liquid ejection head manufactured according to this method, and more particularly, it relates to a method of manufacturing a fine wiring substrate having good adhesive properties and to a liquid ejection head manufactured according to this method.

2. Description of the Related Art

In recent years, there has been a tendency for the various electronic components which are used in an electronic device to be integrated at higher density, in accordance with reductions in the weight and size of these electronic devices. In response to this, the electrical wiring patterns of the wiring substrate with which various electronic components are mounted are formed to become higher density, and the line width of the electrical wirings or the interval between the wirings is required to have very fine dimensions of the order of approximately 10 μm (L/S≈10 μm/10 μm), for instance. Accordingly, the bonding surface between the substrate and the extremely fine electrical wires supported by the substrate inevitably becomes smaller. Therefore, there is a possibility of declining the adherence between the electrical wires and the substrate, that is to say, close-contact characteristics therebetween.

More specifically, there is a commonly used method of forming fine wirings in which electrical wires are formed by photolithography. In this method, the contact section between an electrical wire and the substrate is formed on one surface only, and therefore, the finer the electrical wires, the weaker the adhesive characteristics tend to become. In particular, if there is a vibration generating section or operating section on or near the substrate, then the electrical wires may become detached from the substrate due to vibrations caused by the vibrating section or operating section, and this may lead to functional problems.

Japanese Patent Application Publication No. 2001-85358 discloses a method in which an insulating layer is formed so as to make contact with both lateral faces of each electrical wire, prior to forming the electrical wires. Since each electrical wire formed in this method makes contact with the insulating layer at both lateral faces of the electrical wire, in addition to making contact with the substrate surface, then the electrical wire makes contact with other materials in three surfaces thereof. Therefore, the adherence of each electrical wire is stronger than that in a case where each electrical wire makes contact with the substrate surface only (one surface).

In the method disclosed in Japanese Patent Application Publication No. 2001-85358, a zinc oxide layer is formed and is then immersed in an aqueous solution of copper sulfate, whereby zinc is substituted by copper and copper is deposited. Electrical wires are thus formed in the portions where the copper is exposed. However, the film obtained by this substitution plating has a coarse crystal structure, a large number of pinholes, and poor adhesive characteristics. Therefore, although copper is deposited in substitution for zinc when the zinc oxide is immersed in the aqueous solution of copper sulfate, the adherence between the substrate and the copper forming the electrical wires is degraded.

Moreover, Japanese Patent Application Publication No. 2001-85358 discloses an invention in which the zinc oxide is doped with an alkali metal, such as Li, Na or K. It is previously known that if material of this kind infiltrates into a semiconductor element made of a semiconducting material such as silicon, then the semiconductor element may operate incorrectly and the production yield will fall. In the invention described in Japanese Patent Application Publication No. 2001-85358, the substrate contains an alkali metal as described above, and therefore a substrate of this kind is not suitable for use when a semiconductor element is to be mounted on the substrate and the semiconductor element is to be used.

Moreover, normally, zinc oxide is used as a transparent conductive material, and it has poor insulating properties. Hence, there is a possibility that, if electrical wires are formed on a zinc oxide film, then the current that should flow inside an electrical wire flows into the adjacent electrical wires through the zinc oxide film, and insulation is not achieved between the electrical wires, and consequently the wiring substrate ceases to function correctly. In cases where the zinc oxide is doped with an alkali metal, the resistance tends to decline yet further and this possibility becomes more serious.

### SUMMARY OF THE INVENTION

The present invention has been contrived in view of the foregoing circumstances, an object thereof being to provide a method of readily forming high-density electrical wires having high heat radiating properties and strong adhesion to the substrate, and to provide a liquid ejection head manufactured by means of this method.

In order to attain the aforementioned object, the present invention is directed to a method of manufacturing a wiring substrate, includes the steps of: forming a photocatalyst containing layer which is made of a material containing a photocatalytic material, on a substrate made of an insulating material; forming a resin layer in regions other than wire regions on the photocatalyst containing layer; radiating ultraviolet light on the photocatalyst containing layer while the substrate provided with the resin layer and the photocatalyst containing layer is immersed in a solution containing at least a metal ion and a sacrificial reagent, in such a manner that metal is deposited on exposed regions of the photocatalyst containing layer.

Preferably, a heat radiation region is further formed on the photocatalyst containing layer; and the resin layer is formed in regions other than the wire regions and the heat radiation region on the photocatalyst containing layer.

Preferably, the photocatalytic material has a conduction band of which a lower end is less than a reduction potential of the metal, and has a band gap not less than 3 eV and not greater than 6 eV.

Preferably, the photocatalytic material has a conduction band of which a lower end is less than a potential of a standard hydrogen electrode, and has a band gap not less than 3 eV and not greater than 6 eV.

Preferably, the photocatalytic material is insoluble in water when the ultraviolet light is radiated on the photocatalytic material.

Preferably, the photocatalytic material is one of TiO₂, SrTiO₃, KTaO₃, KTaNbO₃, ZrO₂, and a complex compound containing at least one of TiO₂, SrTiO₃, KTaO₃, KTaNbO₃, and ZrO₂.

Preferably, the ultraviolet light has a wavelength not less than 210 nm and not greater than 420 nm.

Preferably, the resin layer is manufactured by one of a photolithography method and an imprint method.

Preferably, the solution contains at least one of a copper ion, a silver ion, a gold ion, and a platinum ion.

In order to attain the aforementioned object, the present invention is also directed to a liquid ejection head having a wiring substrate manufactured by means of a method of manufacturing a wiring substrate, including the steps of: forming a photocatalyst containing layer which is made of a material containing a photocatalytic material, on a substrate made of an insulating material; forming a resin layer in regions other than wire regions on the photocatalyst containing layer; radiating ultraviolet light on the photocatalyst containing layer while the substrate provided with the resin layer and the photocatalyst containing layer is immersed in a solution containing at least a metal ion and a sacrificial reagent, in such a manner that metal is deposited on exposed regions of the photocatalyst containing layer.

The present invention is beneficial in that it is possible to readily form high-density electrical wires having good heat radiating properties and good adhesion with respect to the substrate. Moreover, a liquid ejection head can be made more compact in size by using a circuit substrate manufactured according to the present invention.

### BRIEF DESCRIPTION OF THE DRAWINGS

The nature of this invention, as well as other objects and benefits thereof, will be explained in the following with reference to the accompanying drawings, in which like reference characters designate the same or similar parts throughout the figures and wherein:

FIGS. 1A to 1F are illustrative diagrams showing a method of manufacturing a wiring substrate according to a first embodiment of the present invention;

FIG. 2 is a cross-sectional diagram of a wiring substrate manufactured according to an embodiment of the present invention;

FIG. 3 is a cross-sectional diagram showing another mode of a wiring substrate manufactured according to an embodiment of the present invention;

FIG. 4 is a cross-sectional diagram showing another mode of a wiring substrate manufactured according to an embodiment of the present invention;

FIG. 5 is a cross-sectional diagram showing a liquid ejection head according to an embodiment of the present invention;

FIGS. 6A to 6F are illustrative diagrams showing a first method of manufacturing a wiring substrate according to a second embodiment of the present invention;

FIG. 7 is an illustrative diagram showing the band structure of photocatalytic materials and the oxidation-reduction potential of water;

FIGS. 8A to 8F are illustrative diagrams showing a second method of manufacturing a wiring substrate according to the second embodiment of the present invention; and

FIGS. 9A to 9D are partial illustrative diagrams showing the second method of manufacturing a wiring substrate according to the second embodiment of the present invention.

### DETAILED DESCRIPTION OF THE PREFERRED EMBODIMENTS

### First Embodiment

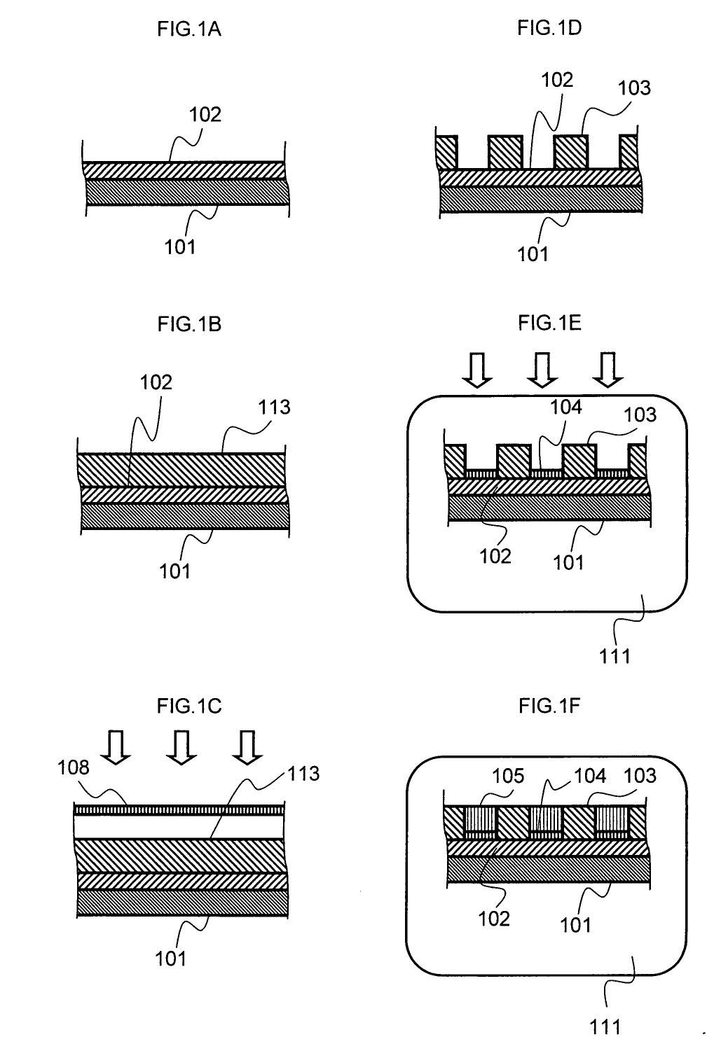

FIGS. 1A to 1F are diagrams showing a method of manufacturing a wiring substrate according to a first embodiment of the present invention. The first embodiment relates to a method of manufacturing a wiring substrate by means of photolithography.

As shown in FIG. 1A, a photocatalyst containing layer 102 is formed on a substrate 101 made of an insulator material.

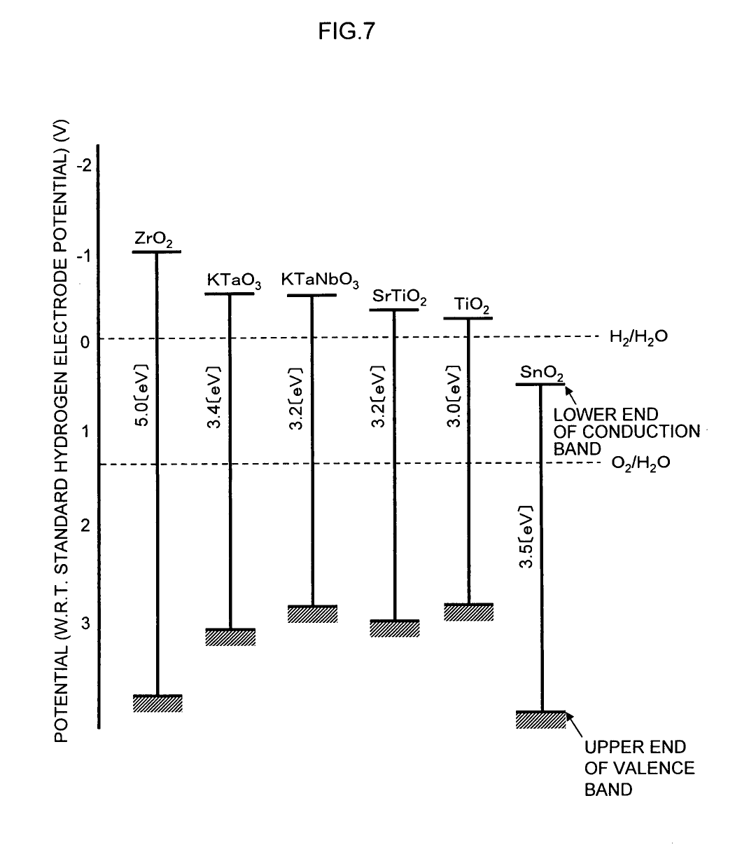

The substrate 101 is formed of a glass substrate, a silicon wafer, a resin substrate, a ceramic substrate, or the like. The photocatalyst containing layer 102 contains a photocatalytic material which displays photocatalytic activity when irradiated with ultraviolet light. In the present embodiment, the photocatalytic material is required to meet some conditions, as described below with reference to FIG. 7.

It is necessary that the photocatalytic material used in the present embodiment should be capable of directly reducing the target metal material.

The reduction potential (in the reduction of a copper ion (Cu²⁺) to a copper metal) of copper is +0.337 (V), the reduction potential (in the reduction of a silver ion (Ag⁺) to a silver metal) of silver is +0.799 (V), the reduction potential (in the reduction of a platinum ion (Pt⁺) to a platinum metal) of platinum is +1.188 (V), and the reduction potential (in the reduction of a gold ion (Au³⁺) to a gold metal) of gold is +1.52 (V). The lower end of the conduction band of the photocatalytic material is required to be sufficiently less than these potentials. Moreover, if copper is used as the electrical wire material, for example, then the lower end of the conduction band of the photocatalytic material is required to be at least less than the hydrogen generating potential, in consideration of overvoltage. The hydrogen generating potential is the potential of the standard hydrogen electrode (SHE). The standard hydrogen electrode is used as the reference of electrode potentials, and the potential of SHE is expressed as follows: H₂/H₂O=0 (V).

Moreover, the band gap of the photocatalytic material used in the present embodiment is required to be not less than 3 eV and not greater than 6 eV. This is because, the photocatalyst containing layer 102 on which the electrical wires are formed is required not to be conductive at an ordinary temperature, in order to ensure insulation between the wires. Moreover, it is also impossible to use a material which may readily cause excitation of electrons due to a low-energy electromagnetic wave, or the like. Therefore, the band gap of the photocatalytic material is required to be 3 eV or above.

Moreover, if the band gap is too broad, then the excitation is not possible by means of light having wavelengths in the ultraviolet region, and therefore the band gap is required to be 6 eV or below, in order that the photocatalyst is activated by the ultraviolet light.

The photocatalytic material in the present embodiment must be poorly soluble, and is preferably insoluble in water. Moreover, even if light such as ultraviolet light is radiated on the photocatalytic material, the photocatalytic material must remain poorly soluble, and the photocatalytic material preferably remains insoluble in water. This is because the solution used in the present embodiment, such as the electroless plating solution, is usually an aqueous solution containing water, and if the photocatalytic material is soluble in water, or if it becomes soluble in water when irradiated with light such as ultraviolet light, then the photocatalytic material is dissolved by the immersion in the solution such as the electroless plating liquid.

Therefore, zinc oxide, sulfide semiconducting compound and selenide semiconducting compound may not be used as a photocatalytic material according to the present embodiment, even though these materials can function as a photocatalytic material. This is because these materials dissolve in the aqueous solution or dissolve in the aqueous solution by photoinduced oxidation when irradiated with light.

Accordingly, preferable photocatalytic materials which can be used in the present embodiment are: titanium oxide (TiO₂) which has a band gap of 3.0 eV (corresponding to an electromagnetic wave having a wavelength of 41 nm); strontium titanate (SrTiO₃) which has a band gap of 3.2 eV (corresponding to an electromagnetic wave having a wavelength of 388 nm); potassium tantalate (KTaO₃) which has a band gap of 3.4 eV (corresponding to an electromagnetic wave having a wavelength of 365 nm); potassium tantalate niobate (KTaNbO₃) which has a band gap of 3.2 eV (corresponding to an electromagnetic wave having a wavelength of 388 nm); zirconium oxide (ZrO₂) which has a band gap of 5.0 eV (corresponding to an electromagnetic wave having a wavelength of 248 nm); or a composite of these compounds. Among these materials, it is more preferable to use TiO₂ as a photocatalytic material, since TiO₂ is most commonly used as a photocatalyst and has high durability.

The photocatalyst containing layer 102 may be composed of photocatalytic material only. Moreover, the photocatalyst containing layer 102 may contain a binder material in addition to the photocatalyst material in order to increase adhesion to the substrate 101. In this case, heat treatment may be carried out in order to solidify the binder.

In cases where the photocatalyst containing layer 102 contains photocatalytic particles, the surface of the photocatalyst containing layer 102 has an undulating shape. Due to this undulation shape, the surface area of the photocatalyst containing layer 102 is increased, and accordingly the adhesive force (adhesion of a resin layer or a metallic layer to the photocatalyst containing layer 102) is increased when the resin layer and metallic layer are formed in subsequent steps. The photocatalyst containing layer 102 is also required to fulfill a heat radiating function, and therefore it should be formed to have a thickness of 0.1 μm to 100 μm. Moreover, the smaller the photocatalytic particles, the higher the efficiency of the photocatalytic activity. In consideration of the electrical wires that are to be formed in the subsequent steps, the particles should be 1 μm or below. On the other hand, if the particles are too small, then no undulations at all are formed on the surface of the photocatalyst containing layer 102. Therefore, taking into account both the efficiency of the photocatalytic activity and the thickness requirement of the photocatalyst containing layer 102, it is desirable that the size of the photocatalytic particles included in the photocatalytic material should be 0.01 μm to 1 μm.

Next, as shown in FIG. 1B, a resist layer 113 is formed on the photocatalyst containing layer 102. More specifically, the material of the resist layer 113 is a permanent type of a photo-curable epoxy resist. This resist is applied on the photocatalyst containing layer 102 supported by the substrate 101, by means of spin coating, or the like. Subsequently, pre-baking is carried out, and then the resist layer 113 is exposed to ultraviolet light radiated in the direction of the arrow from an ultraviolet light irradiation apparatus having a mask aligner, or the like. In this case, an exposure mask 108 formed with a pattern is used as shown in FIG. 1C, whereby the resin layer 103 is formed only in the non-wire regions (the regions where electrical wires are not to be formed). In this step, the ultraviolet light is used for exposing the resist layer 113. By immersing the resist layer 113 in a development solution after the exposure, the resist layer 113 is developed. Consequently, the resin layer 103 is formed on the photocatalyst containing layer 102, in the non-wire regions only, as shown in FIG. 1D.

In this way, on the substrate 101, the photocatalyst containing layer 102 is exposed (uncovered) in the wire regions and the photocatalyst containing layer 102 is covered with the resin layer 103 in the non-wire regions, and consequently a pattern is formed.

Next, as shown in FIG. 1E, the substrate 101 formed with the pattern in this way is immersed in a solution containing at least a metal ion and a sacrificial reagent inside an electroless plating tank 111. The surface of the substrate on which the resin layer 103 has been formed is then irradiated with ultraviolet light transmitted in the direction indicated by the arrow. In this step, the ultraviolet light is used for activating the photocatalytic material (for photocatalytic activation of the photocatalytic material).

For the solution containing at least a metal ion and a sacrificial reagent, a solution containing an ion of copper (Cu), silver (Ag), gold (Au), platinum (Pt), or the like, as the metal ion, and formaldehyde, methanol, ethanol, formic acid, or an organic acid, as the sacrificial reagent, is used. Electrons and positive holes are generated in the photocatalyst containing layer 102 due to the irradiation of ultraviolet light. The sacrificial reagent reacts with the positive hole thus generated, and the electrons are used for the reduction of the metal ion. In the present embodiment, an electroless plating solution is used for the solution containing at least such a metal ion and such a sacrificial reagent, since the electroless plating solution generally contains the aforementioned metal ion and sacrificial reagent.

A suitable wavelength for the radiated ultraviolet light is 210 nm to 420 nm, depending on the band gap of the photocatalytic material contained in the photocatalyst containing layer 102.

Due to the radiation of ultraviolet light on the uncovered (exposed) surface of the photocatalyst containing layer 102, the photocatalytic material is activated and metal deposits on this region, thereby forming a metal deposition layer 104. If the metal deposition layer 104 is immersed in an electroless plating solution after the metal deposition layer 104 has been formed, then an electroless plating reaction occurs on the surface of the metal deposition layer 104, and thereby a metal film 105 is formed on the metal deposition layer 104. Since the electroless plating solution generally contains a metal ion and a sacrificial reagent, then it is possible to immerse the photocatalyst containing layer 102 in an electroless plating solution and to radiate ultraviolet light (in other words, the electroless plating solution may be used for both forming the metal deposition layer 104 and forming the metal film 105). In this case, ultraviolet light needs to be radiated only in the initial stage. Since the photocatalyst containing layer 102 itself does not have catalytic activity for the electroless plating reaction, metal is not deposited on the photocatalyst containing layer 102 simply by immersing the photocatalyst containing layer 102 in the electroless plating solution inside the electroless plating tank 111. Therefore, ultraviolet light is required to be initially radiated on the photocatalyst containing layer 102, in such a manner that the photocatalytic material is activated and deposition of metal contained in the electroless plating solution begins. The metal deposition layer 104 itself has catalytic activity for the electroless plating reaction. Therefore, once a metal deposition layer 104 is formed on substantially the whole surface of the uncovered photocatalyst containing layer 102, then the metal continues to be deposited even if the radiation of the ultraviolet light is halted. The metal is thus deposited on the metal deposition layer 104 only in regions where the resin layer 103 has not been formed, thereby forming a metal layer 105 as shown in FIG. 1F.

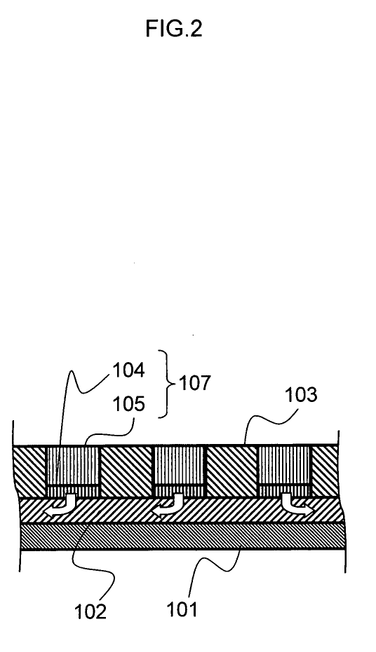

FIG. 2 is a diagram showing a wiring substrate manufactured by means of the steps described above.

The photocatalyst containing layer 102 is formed over the whole surface of the substrate 101, the resin layer 103 is formed in the non-wire regions on the photocatalyst containing layer 102, and the electrical wires 107 constituted by the metal deposition layer 104 and the metal layer 105 are formed in the wire regions.

As shown in FIG. 2, the electrical wires 107 constituted by the metal deposition layer 104 and the metal layer 105 make contact with material in three directions, in other words, the electrical wires 107 are surrounded by the photocatalyst containing layer 102 and the resin layer 103 supported by the substrate 101. Therefore, the adhesive force of the electrical wire 107 is strengthened. Moreover, the heat generated when current is passed through the electrical wires 107, each of which is constituted by the metal deposition layer 104 and the metal layer 105, flows in the directions indicated by the arrows in FIG. 2, through the photocatalyst containing layer 102, and thereby the heat generated can be radiated.

### Heat Radiating Layer

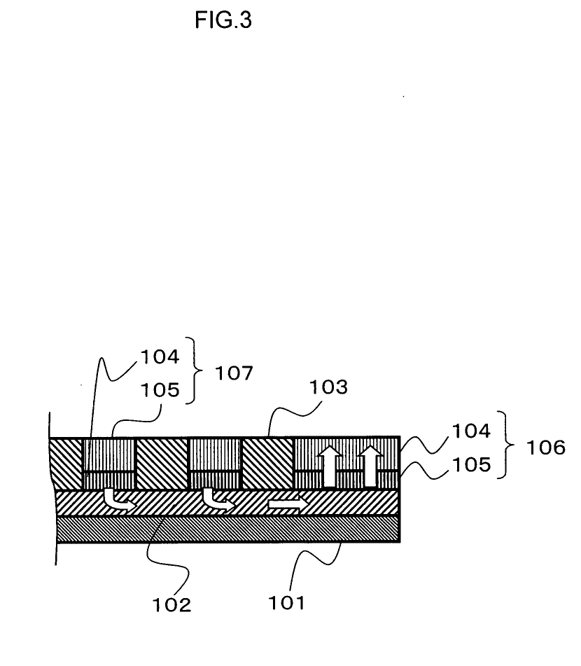

FIG. 3 is a diagram showing a wiring substrate having a composition which enhances heat radiation effects. In this wiring substrate, the electrical wires 107 and a heat radiation layer 106 are formed simultaneously.

FIG. 3 shows a substrate 101 formed with the heat radiation layer 106.

After forming a photocatalyst containing layer 102 on the whole surface of the substrate 101, a resin layer 103 is formed in regions which are the non-wire and non-heat-radiation regions (i.e., regions other than the wire regions and the heat radiation regions). In other words, the resin layer 103 is formed in the regions apart from the regions where the electrical wires 107 or the heat radiation layer 106 are to be formed subsequently. After that, by forming a metal deposition layer 104 and a metal layer 105, the electrical wires 107 and the heat radiation layer 106 can be formed simultaneously.

In this wiring substrate thus produced, even if heat is generated when current passes through the electrical wires 107, the heat flows in the directions of the arrows and is transferred to the heat radiation layer 106, via the photocatalyst containing layer 102, and is radiated.

If the substrate 101 is made of resin or glass, then the material constituting the photocatalyst containing layer 102 generally has a higher thermal conductivity than that of the substrate 101, and hence the improved beneficial effects can be obtained especially in the case of the substrate made of resin or glass.

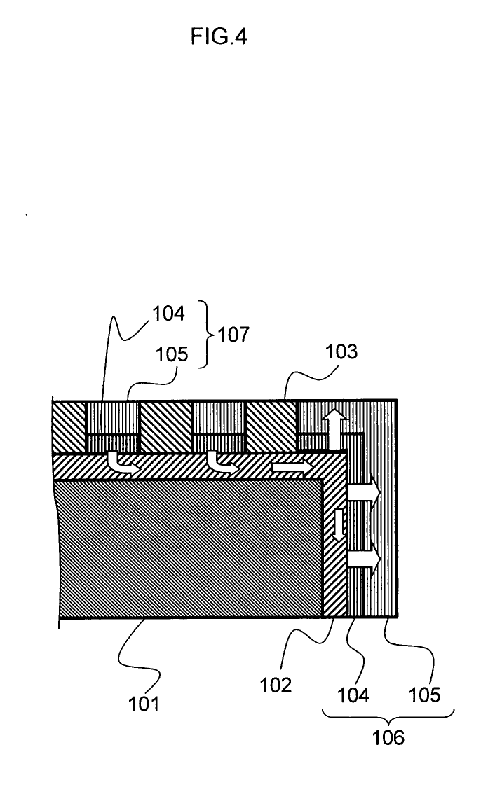

FIG. 4 is a diagram showing a modified embodiment in which the photocatalyst containing layer 102 is formed on the three-dimensional substrate 101 (the photocatalyst containing layer 102 extends so as to have a three-dimensional arrangement), and the resin layer 103 is formed thereon, whereupon the metal deposition layer 104 and the metal layer 105 are formed to create the electrical wires 107 and the heat radiation layer 106. In this case also, the heat flows in the directions of the arrows in FIG. 4, and thereby a heat radiating effect can be obtained.

### Liquid Ejection Head

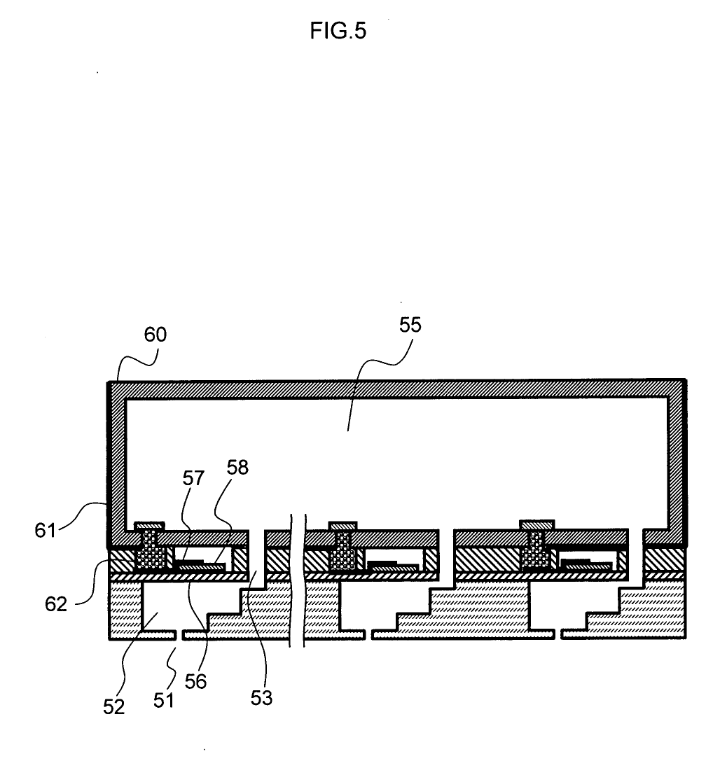

Next, a liquid ejection head fabricated by using the substrate manufactured by the method according to the present embodiment is described with reference to FIG. 5.

The liquid ejection head manufactured according to the present embodiment has nozzles 51, pressure chambers 52, and supply ports 53. If an electric field is applied to each piezoelectric element 58 that is interposed between an individual electrode 57 and a common electrode 56, which also serves as a diaphragm, then the diaphragm deforms and the ink inside the corresponding pressure chamber 52 is ejected from the corresponding nozzle 51. Each individual electrode 57 is connected to an electrical wire 61 formed on a wall surface defining the common liquid chamber 55, via a through electrode 62. The electrical wires 61 formed on the wall surface 60 of the common liquid chamber 55 are manufactured by means of the manufacturing method according to the present embodiment described above, by taking the wall (the wall surface 60) as the substrate 101. Since the electrical wires 61 are embedded in the wall surface 60, then the electrical wires 61 have strong adhesion and do not become detached from the wall surface due to fine vibrations occurring when the piezoelectric elements 58 are driven, or due to the driving of the liquid ejection head.

### Second Embodiment

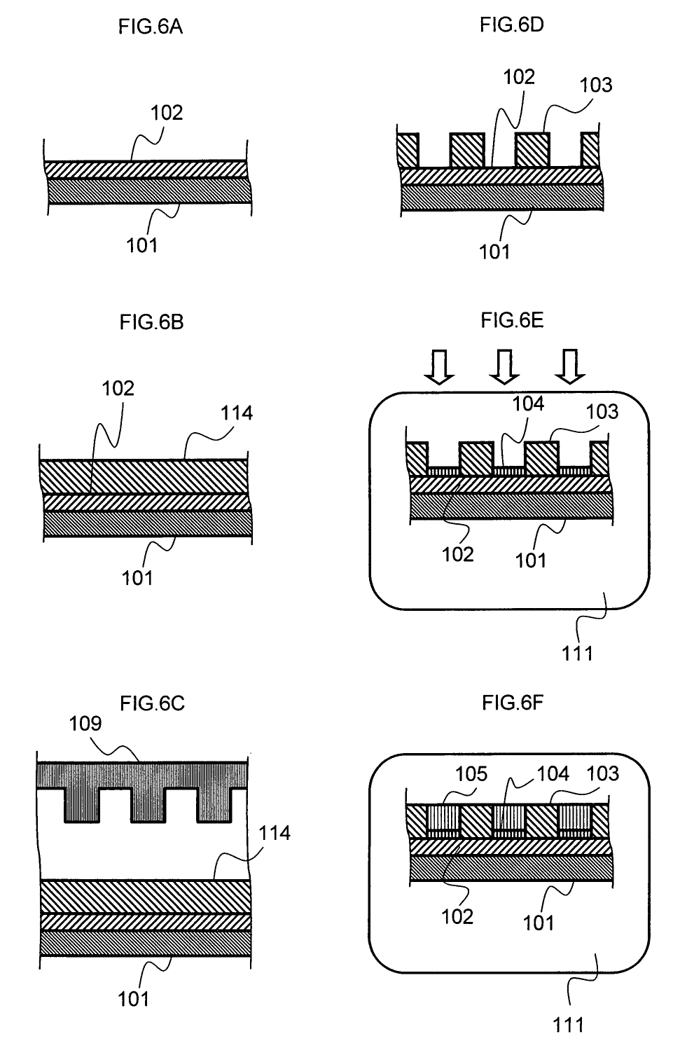

FIGS. 6A to 6F are diagrams showing a method of manufacturing a wiring substrate according to a second embodiment of the present invention. The second embodiment relates to a method in which a wiring substrate is manufactured by imprinting.

As shown in FIG. 6A, a photocatalyst containing layer 102 is formed on a substrate 101 made of an insulator material.

The substrate 101 is made of a glass substrate, a silicon wafer, a resin substrate, a ceramic substrate, or the like. The photocatalyst containing layer 102 contains a photocatalytic material which displays photocatalytic activity when irradiated with ultraviolet light. In the present embodiment, the photocatalytic material is required to meet some conditions, as described below with reference to FIG. 7.

More specifically, it is necessary that the photocatalytic material used in the present embodiment should be capable of directly reducing the target metal material.

The reduction potential (in the reduction of a copper ion (Cu²⁺) to a copper metal) of copper is +0.337 (V), the reduction potential (in the reduction of a silver ion (Ag⁺) to a silver metal) of silver is +0.799 (V), the reduction potential (in the reduction of a platinum ion (Pt⁺) to a platinum metal) of platinum is +1.188 (V), and the reduction potential (in the reduction of a gold ion (Au³⁺) to a gold metal) of gold is +1.52 (V). The lower end of the conduction band of the photocatalytic material is required to be sufficiently less than these potentials. For example, if copper is used as the electrical wire material, then the lower end of the conduction band of the photocatalytic material is required to be at least less than the hydrogen generating potential, in consideration of overvoltage. The hydrogen generating potential is the potential of the standard hydrogen electrode (SHE). The standard hydrogen electrode is used as the reference of electrode potentials, and the potential of SHE is expressed as follows: H₂/H₂O=0 (V).

Moreover, the band gap of the photocatalytic material used in the present embodiment is required to be not less than 3 eV and not greater than 6 eV. This is because, the photocatalyst containing layer 102 on which the electrical wires are formed is required not to be conductive at an ordinary temperature, in order to ensure insulation between wires. Moreover, it is also impossible to use a material which may readily cause excitation of electrons due to a low-energy electromagnetic wave, or the like. Therefore, the band gap of the photocatalytic material must be 3 eV or above.

Moreover, if the band gap is too broad, then the excitation is not possible by means of light having wavelengths in the ultraviolet region, and therefore the band gap must be 6 eV or below, in order that the photocatalyst is activated by the ultraviolet light.

The photocatalytic material in the present embodiment must be poorly soluble, and is preferably insoluble in water. Moreover, even if light such as ultraviolet light is radiated on the photocatalytic material, the photocatalytic material must remain poorly soluble, and the photocatalytic material preferably remains insoluble in water. This is because the solution used in the present embodiment, such as the electroless plating solution, is usually an aqueous solution containing water, and if the photocatalytic material is soluble in water, or if it becomes soluble in water when irradiated with light such as ultraviolet light, then the photocatalytic material is dissolved by immersing the photocatalytic material in the solution such as an electroless plating liquid.

Therefore, it is difficult to use zinc oxide, sulfide semiconducting compound and selenide semiconducting compound, as a photocatalytic material according to the present embodiment, even though these materials can function as a photocatalytic material. This is because these materials dissolve in the aqueous solution, or dissolve by photoinduced oxidation in the aqueous solution when irradiated with light.

Accordingly, preferable photocatalytic materials which can be used in the present embodiment are: titanium oxide (TiO₂) which has a band gap of 3.0 eV (corresponding to an electromagnetic wave having a wavelength of 410 nm); strontium titanate (SrTiO₃) which has a band gap of 3.2 eV (corresponding to an electromagnetic wave having a wavelength of 388 nm); potassium tantalate (KTaO₃) which has a band gap of 3.4 eV (corresponding to an electromagnetic wave having a wavelength of 365 nm); potassium tantalate niobate (KTaNbO₃) which has a band gap of 3.2 eV (corresponding to an electromagnetic wave having a wavelength of 388 nm); zirconium oxide (ZrO₂) which has a band gap of 5.0 eV (corresponding to an electromagnetic wave having a wavelength of 248 nm); or a composite of these compounds. Among these materials, it is more preferable to use TiO₂ as a photocatalytic material, since TiO₂ is most commonly used as a photocatalyst and has high durability.

The photocatalyst containing layer 102 may be composed of photocatalytic material only. Moreover, the photocatalyst containing layer 102 may contain a binder material in addition to the photocatalyst material, in order to increase adhesion to the substrate 101. In this case, heat treatment may be carried out in order to solidify the binder.

In cases where the photocatalyst containing layer 102 contains photocatalytic particles, the surface of the photocatalyst containing layer 102 has an undulating shape. Due to this undulation shape, the surface area of the photocatalyst containing layer 102 is increased, and accordingly the adhesive force (adhesion of a resin layer or a metallic layer to the photocatalyst containing layer 102) is increased when the resin layer and metallic layer are formed in subsequent steps. The photocatalyst containing layer 102 is also required to fulfill a heat radiating function, and therefore it must be formed to have a thickness of 0.1 μm to 100 μm. Moreover, the smaller the photocatalytic particles, the higher the efficiency of the photocatalytic activity. In consideration of the electrical wires that are to be formed in the subsequent steps, the particles should be 1 μm or below. On the other hand, if the particles are too small, then no undulations at all are formed on the surface of the photocatalyst containing layer 102. Therefore, taking into account both the efficiency of the photocatalytic activity and the thickness requirement of the photocatalyst containing layer 102, it is desirable that the size of the photocatalytic particles forming the photocatalytic material should be 0.01 μm to 1 μm.

Next, a resin layer 114 is formed on the photocatalyst containing layer 102. More specifically, a thermoplastic resin material or a photo-curable resin material is used as the material of the resin layer 114. As shown in FIG. 6B, the resin layer 114 is formed by applying resin material to the photocatalyst containing layer 102 on the substrate 101. Subsequently, as shown in FIG. 6C, a metal die 109 projecting in the regions where the electrical wires are to be formed is pressed against the resin layer 114 in such a manner that a resin layer 103 is formed only in the non-wire regions. By this means, the resin layer 103 is formed in the non-wire regions, as shown in FIG. 6D.

More specifically, in a case where a thermoplastic resin material is used as the resin layer 114, after heating the whole of the substrate 101 in order to soften the resin film 114, the resin layer 114 is cooled while the metal die 109 is pressed against the resin layer 114. Thereby, the thermoplastic material constituting the resin layer 114 is cured. Subsequently, the metal die 109 is removed, and consequently the resin layer 103 is formed in the non-wire regions.

In cases where a photo-curable resin material is used as the resin layer 114, then after pressing the metal die 109 against the resin layer 114 applied on the substrate 101, light having a prescribed wavelength is radiated on the resin layer 114. Thereby, the photo-curable resin material constituting the resin layer 114 is cured. Subsequently, the metal die 109 is removed, and consequently the resin layer 103 is formed in the non-wire regions.

The metal die 109 used in this step is made of nickel (Ni), or the like. If resin material is left in the wire regions where the resin layer 114 must be removed, then the resin material is sublimated by radiating laser light on the corresponding portions, or it is removed by the ashing process using an oxygen plasma, or the like.

In such an imprint method, the resin layer 103 is formed by pressing the metal die 109 against the resin; therefore this method has benefits in that the equipment, and the like, can be simple, the costs can be low, and the manufacture can be completed in a short period of time.

In this way, on the substrate 101, the photocatalyst containing layer 102 is exposed (uncovered) in the wire regions and the photocatalyst containing layer 102 is covered with the resin layer 103 only in the non-wire regions, and consequently a pattern is formed.

Next, as shown in FIG. 6E, the substrate 101 formed with a pattern in this way is immersed in a solution containing at least a metal ion and a sacrificial reagent inside an electroless plating tank 111. The surface of the substrate 101 on which the resin layer 103 has been formed is then irradiated with ultraviolet light transmitted in the direction indicated by the arrow. In this step, the ultraviolet light is used for activating the photocatalytic material.

For the solution containing at least a metal ion and a sacrificial reagent, a solution containing an ion of copper (Cu), silver (Ag), gold (Au), platinum (Pt), or the like, as the metal ion, and formaldehyde, methanol, ethanol, formic acid, or an organic acid, as the sacrificial reagent, is used. Electrons and positive holes are generated in the photocatalyst containing layer 102 due to the radiation of ultraviolet light. The sacrificial reagent reacts with the positive hole thus generated, and the electrons are used for the reduction of the metal ion. In the present embodiment, an electroless plating solution is used for the solution containing at least the metal ion and the sacrificial reagent.

A suitable wavelength for the radiated ultraviolet light is 210 nm to 420 nm, depending on the band gap of the photocatalytic material contained in the photocatalyst containing layer 102.

Due to the radiation of ultraviolet light on the uncovered (exposed) surface of the photocatalyst containing layer 102, the photocatalytic material is activated and metal deposits on this region, thereby forming a metal deposition layer 104. If the metal deposition layer 104 is immersed in an electroless plating solution after the metal deposition layer 104 has been formed, then an electroless plating reaction occurs on the surface of the metal deposition layer 104 and a metal film 105 is formed thereon. Since the electroless plating solution generally contains a metal ion and a sacrificial reagent, then it is possible to immerse the photocatalyst containing layer 102 directly in an electroless plating solution and to radiate ultraviolet light (in other words, the electroless plating solution may be used for both forming the metal deposition layer 104 and forming the metal film 105). In this case, ultraviolet light needs to be radiated only in the initial stage. Since the photocatalyst containing layer 102 itself does not have catalytic activity for the electroless plating reaction, metal is not deposited on the photocatalyst containing layer 102 simply by immersing the photocatalyst containing layer 102 in the electroless plating solution inside the electroless plating tank 111. Therefore, ultraviolet light is required to be radiated on the photocatalyst containing layer 102 in the initial stage, in such a manner that the photocatalytic material is activated, and deposition of metal contained in the electroless plating solution begins. The metal deposition layer 104 itself has catalytic activity for the electroless plating reaction. Therefore, once a metal deposition layer 104 is formed on substantially the whole surface of the uncovered photocatalyst containing layer 102, then the metal continues to be deposited even if the radiation of the ultraviolet light is halted. The metal is thus deposited only on the metal deposition layer 104 in regions where the resin layer 103 has not been formed, thereby forming a metal layer 105 as shown in FIG. 6F.

By means of the steps described above, it is possible to manufacture a wiring substrate as shown in FIG. 2.

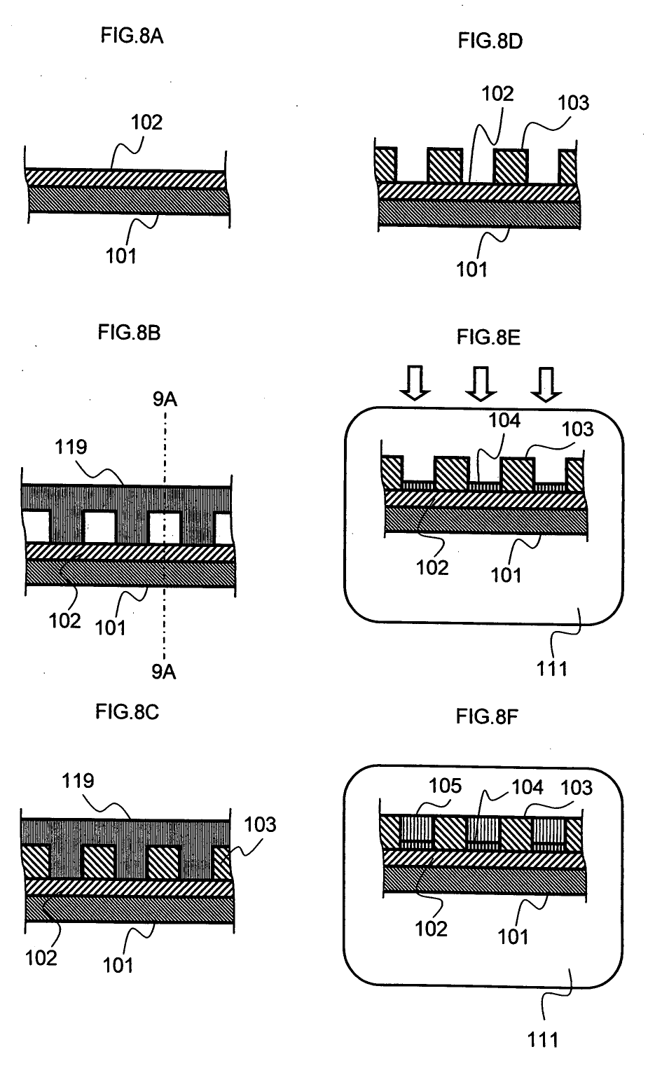

Another forming method according to the present embodiment is described below with reference to FIGS. 8A to 8F. Initially, a photocatalyst containing layer 102 is formed on a substrate 101 made of an insulating material, as shown in FIG. 8A, similarly to the step shown in FIG. 6A. Subsequently, as shown in FIG. 8B, a die 119 having recess sections at regions where a resin layer 103 is to be formed in a subsequent step, is placed in close contact with the photocatalyst containing layer 102 on the substrate 101. Desirably, the die 119 has flexibility, in order to improve the close contact characteristics, and a material such as polydimethylsiloxane (PDMS), or the like, is suitable for this die 119.

Thereupon, while the die is in the state of close contact, resin material is injected into spaces between the die 119 and the photocatalyst containing layer 102 supported by the substrate 101, and then the resin material is cured.

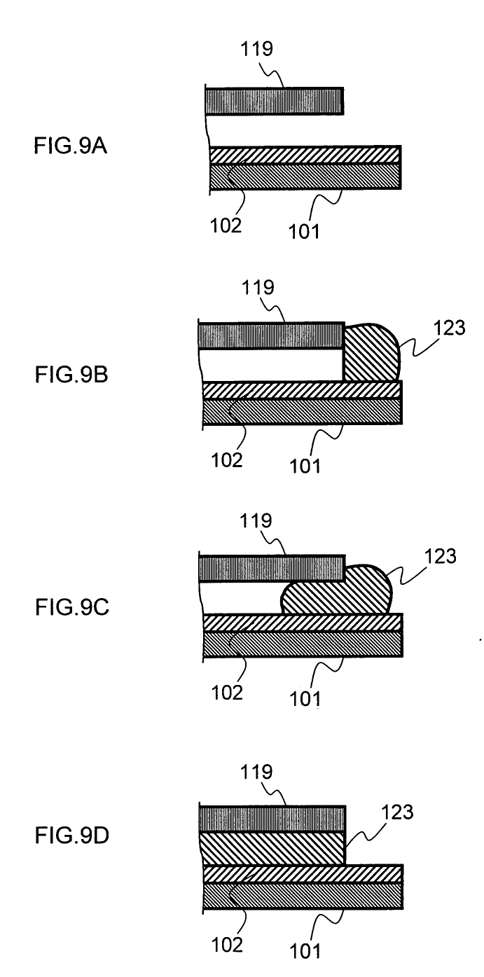

The method of injecting the resin material is described below in detail with reference to FIGS. 9A to 9D. FIG. 9A is a cross-sectional diagram of a vertical section taken along line 9A-9A in FIG. 8B. As shown in FIG. 9B, a reduced pressure state is created and resin material 123 is arranged so as to block off the spaces between the die 119 and the photocatalyst containing layer 102 on the substrate 101. Thereupon, the pressure is returned from the reduced pressure state to normal pressure (atmospheric pressure). Thereby, as shown in FIG. 9C, the resin material 123 enters the spaces between the die 119 and the photocatalyst containing layer 102 supported by the substrate 101. By maintaining this state, as shown in FIG. 9D, the resin material 123 completely enters the spaces between the die 119 and the photocatalyst containing layer 102 on the substrate 101. Thereupon, a resin layer 103 is formed by curing this resin material 123, as shown in FIG. 8C. Method of injecting resin material may include other methods apart from the above-described method.

In this method, since no resin material is left in the wire regions where the resin layer 114 should be removed, then film removal process using radiation of laser light or ashing process using an oxygen plasma is not required.

Thereupon, as shown in FIG. 8D, by removing the die 119, the resin layer 103 is formed on the photocatalyst containing layer 102 on the substrate 101. Next, similarly to the step described in FIG. 6E, the substrate is immersed in a solution containing at least a metal ion and a sacrificial reagent inside an electroless plating tank 111, whereupon ultraviolet light is radiated in the direction of the arrow, thereby forming a metal deposition layer 104. Thereupon, as shown in FIG. 8F, metal is deposited on the metal deposition layer 104 to form a metal layer 105, and consequently a wiring substrate shown in FIG. 2 can be manufactured.

Methods of manufacturing a wiring substrate and liquid ejection heads manufactured by these methods according to the present invention have been described in detail above, but it should be understood that there is no intention to limit the invention to the specific forms disclosed, but on the contrary, the invention is to cover all modifications, alternate constructions and equivalents falling within the spirit and scope of the invention as expressed in the appended claims.

What is claimed is:

1. A method of manufacturing a wiring substrate, the method including the steps of:
forming a photocatalyst containing layer which is made of a material containing a photocatalytic material, on a substrate made of an insulating material;
forming a resin layer in regions other than wire regions on the photocatalyst containing layer;
radiating ultraviolet light on the photocatalyst containing layer while the substrate provided with the resin layer and the photocatalyst containing layer is immersed in a solution containing at least a metal ion and a sacrificial reagent, in such a manner that metal is deposited on exposed regions of the photocatalyst containing layer.

2. The method of manufacturing a wiring substrate as defined in claim 1, wherein:
a heat radiation region is further formed on the photocatalyst containing layer; and
the resin layer is formed in regions other than the wire regions and the heat radiation region on the photocatalyst containing layer.

3. The method of manufacturing a wiring substrate as defined in claim 1, wherein the photocatalytic material has a conduction band of which a lower end is less than a reduction potential of the metal, and has a band gap not less than 3 eV and not greater than 6 eV.

4. The method of manufacturing a wiring substrate as defined in claim 1, wherein the photocatalytic material has a conduction band of which a lower end is less than a potential of a standard hydrogen electrode, and has a band gap not less than 3 eV and not greater than 6 eV.

5. The method of manufacturing a wiring substrate as defined in claim 3, wherein the photocatalytic material is insoluble in water when the ultraviolet light is radiated on the photocatalytic material.

6. The method of manufacturing a wiring substrate as defined in claim 4, wherein the photocatalytic material is insoluble in water when the ultraviolet light is radiated on the photocatalytic material.

7. The method of manufacturing a wiring substrate as defined in claim 3, wherein the photocatalytic material is one of TiO₂, SrTiO₃, KTaO₃, KTaNbO₃, ZrO₂, and a complex compound containing at least one of TiO₂, SrTiO₃, KTaO₃, KTaNbO₃, and ZrO₂.

8. The method of manufacturing a wiring substrate as defined in claim 4, wherein the photocatalytic material is one of TiO₂, SrTiO₃, KTaO₃, KTaNbO₃, ZrO₂, and a complex compound containing at least one of TiO₂, SrTiO₃, KTaO₃, KTaNbO₃, and ZrO₂.

9. The method of manufacturing a wiring substrate as defined in claim 1, wherein the ultraviolet light has a wavelength not less than 210 nm and not greater than 420 nm.

10. The method of manufacturing a wiring substrate as defined in claim 1, wherein the resin layer is manufactured by one of a photolithography method and an imprint method.

11. The method of manufacturing a wiring substrate as defined in claim 1, wherein the solution contains at least one of a copper ion, a silver ion, a gold ion, and a platinum ion.

12. A liquid ejection head having a wiring substrate manufactured by means of the method as defined in claim 1.
